(19) United States
(12) Patent Application Publication
(10) Pub. No.: US 2004/0211954 A1
(43) Pub. Date: Oct. 28, 2004

(54) Compositive laminate substrate with inorganic substrate and organic substrate

(76) Inventors: Shih-Hsien Wu, Hsinchu (TW); Min-Lin Lee, Hsinchu (TW); Shinn-Juh Lay, Hsinchu (TW)

Correspondence Address: BIRCH STEWART KOLASCH & BIRCH, PO BOX 747, FALLS CHURCH, VA, 22040-0747, US

(21) Appl. No.: 10/619,591

(22) Filed: Jul. 16, 2003

(30) Foreign Application Priority Data
Apr. 22, 2003 (TW) 92109338

(51) Int. Cl. H01L 29/06

(52) U.S. Cl. 257/10

(57) ABSTRACT

A compositive laminate substrate applicable for integrated and minimized electronic circuits is composed of at least an inorganic substrate and an organic substrate. The inorganic substrate is embedded with resistors, capacitors and inductors. Through the organic substrate (printed circuit boards), outer I/O ports are connected with the passive components of the inorganic substrate.

### BACKGROUND OF THE INVENTION

1. Field of the Invention

The invention generally relates to a compositive laminate substrate, and particularly relates to a laminate substrate composed of at least an inorganic substrate and an organic substrate for circuit integration applications.

2. Related Art

Under the requirements of high speed and high frequency circuits, the signal rise time in electronic circuits is getting faster and faster that makes the time budget and noise margin become tighter and tighter. In order to minimize the path of signal transmission and reduce the noise plus during signal transmission, components are considering to integrate into substrate by its particular function.

Currently, most electronic circuits are using a lot of surface mount devices (SMD). The electromagnetic interference and variance of SMD component characteristics caused by solder points of the devices are problems hard to be solved especially when the component size is large.

The package size of surface mount device is getting smaller and smaller, from 1210, 1206, 0805, 0603 to 0402, or even 0201. The smaller SMD component will use less solder in SMD connection, therefore improve the performance of SMD component more or less. However, the minimized package area relatively generates additional limitations. For example, when component is getting smaller, the capability to offer capacitance, inductance and resistance is also getting smaller; meanwhile, the distance between components is smaller when smaller SMD components is used to shrink the module size. This situation makes the electromagnetic interference and electronic signal transmission problems even more serious.

In order to reduce the signal voltage fluctuation caused by SMD components, a functional laminate substrate having passive components embedded in the substrate has been developed. The functional laminate substrate eliminates solder points of components on the substrate, and reduces the signal transmission path between components, so as to upgrade the substrate to a functional element beyond the conventional role of simple connecting interface. The functional laminate substrate gives a great improvement in noise reduction, signal transmission path reduction and package integration of electronic systems.

U.S. Pat. No. 5,972,231, titled “Imbedded PCB AC coupling capacitors for high data rate signal transfer”, discloses a method and apparatus for coupling high-speed data components using imbedded PCB AC coupling capacitors. The capacitor is formed by dielectric material covered by correspondent conductive layers formed on upper and lower surfaces of a printed circuit board. Through integrated circuit fabrication process, several layers of the capacitors are constructed by via holes for a required capacity.

Though the capacitors can meet requirements of high-density package, the imbedded materials for passive components in functional laminate substrate are still in development and not matured. For example, currently developed high-k dielectrics material applicable to film capacitors is only at 40 dielectrics. However, a common ceramic material has dielectrics up to 10,000. Therefore, the current high-k dielectric material for imbedded components of laminate still has a long way to go.

U.S. Pat. No. 6,054,754, titled “Multi-capacitance lead frame decoupling device”, discloses an integrated circuit device having a multiple layer lead frame. One layer of the lead frame comprises a first conductive layer of decoupling capacitor. A second layer of the lead frame comprises a second, opposite conductive layer of capacitor. The two layers are joined by an interposed dielectric material to create the capacitor(s). Though the structure can reduce coupling and suppress noise, it is applicable only to a lead frame package but not other packages of great number I/O leads, high performance and high density components.

### SUMMARY OF THE INVENTION

The object of the invention is to provide a compositive laminate substrate including at least an inorganic substrate and an organic substrate. The inorganic substrate is embedded with resistors, capacitors and inductors. Though the organic substrate (printed circuit boards), the compositive laminate is applicable for integrated and minimized electronic circuits.

Forming resistors, capacitors and inductors on a laminate is a known and matured process. The invention uses the known process to form passive components on an inorganic substrate. Then, processing with overlapping, plating, drilling, etching, build-up or other processes to form the organic substrate on the inorganic substrate. The compositive laminate substrate with at least an inorganic substrate and an organic substrate is then finished.

The compositive laminate substrate includes embedded passive components and electrical connecting means for chip carrier and I/O pads. It provides better electrical performance, higher function, higher package density and higher reliability of passive components. It overcomes the material and constructional limitations of conventional carriers that cannot achieve the objectives of high resistance, high capacitance and high inductance.

A compositive laminate substrate made through build-up process further has thinner leads and narrower layout gaps for facilitating a high density, high quantity I/O and minimized integrated circuit board.

### BRIEF DESCRIPTION OF THE DRAWINGS

The invention will become more fully understood from the detailed description given hereinbelow. However, this description is for purposes of illustration only, and thus is not limitative of the invention, wherein:

FIG. 1 is a constructional, sectional view of a first embodiment of the invention;

FIG. 2 is a constructional, sectional view of a second embodiment of the invention;

FIG. 3 is a constructional, sectional view of a third embodiment of the invention;

FIG. 4 is a constructional, sectional view of a fourth embodiment of the invention;

FIG. 5 is a constructional, sectional view of a fifth embodiment of the invention;

FIG. 6 is a constructional, sectional view of a sixth embodiment of the invention; and

FIG. 7 is a constructional, sectional view of a seventh embodiment of the invention;

### DETAILED DESCRIPTION OF THE INVENTION

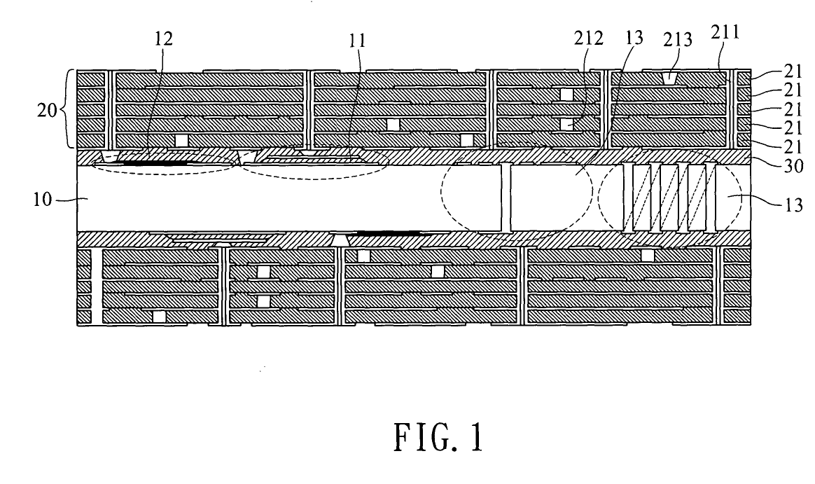

As shown in FIG. 1, a sectional view of a compositive laminate substrate as a first embodiment of the invention mainly includes an inorganic substrate 10 and an organic substrate 20. A bonding layer 30 is formed between the inorganic substrate 10 and the organic substrate 20 for bonding the two.

The inorganic substrate 10 includes at least a passive component, such as a capacitor 11, a resistor 12, an inductor 13 or any combination of these components according to different requirements for the laminate substrate.

Materials for the inorganic substrate 10 are chosen from ceramic, silicon or glass. When using ceramic materials, the known thick film materials for fabricating thick film capacitors, thick film resistors and thick film inductors can be used according to the circuit requirements. The passive components imbedded in the laminate substrate can also be fabricated through thin film processes.

The imbedded inorganic substrate provides higher function, higher package density and higher reliability of the passive components. It overcomes the material and constructional limitations of conventional carriers that cannot achieve the objectives of high resistance, high capacitance and high inductance. The inorganic substrate 10 is covered by the organic substrate 20. I/O pads in the organic substrate 20 provide electrical connections and improve the reliability of the passive components.

When using silicon as material of the inorganic substrate, the thin film capacitors, resistors and inductors are made through photolithography of semiconductor fabrication process. The embedded thin film passive components are therefore made for the compositive laminate substrate.

The organic substrate 20 covers the side of the inorganic substrate 10. Each organic substrate 20 is composed of a plurality of printed circuit boards 21. Each printed circuit board 21 includes circuits for electrical connections of some outer circuits on the printed circuit board 21 to the passive components (capacitors 11, resistance 12 or inductors 13) in the inorganic substrate 10. The number of the printed circuit boards 21 is designed according to the circuit requirements.

Each printed circuit board 21 is made through process of stacking, plating, drilling, etching, and so on. The stacking process includes pressing or bonding. The electrical connections between the passive components and the chip carrier or I/O pads is made by via holes 211, buried holes 212 and blind holes 213 formed on the circuit layers 21.

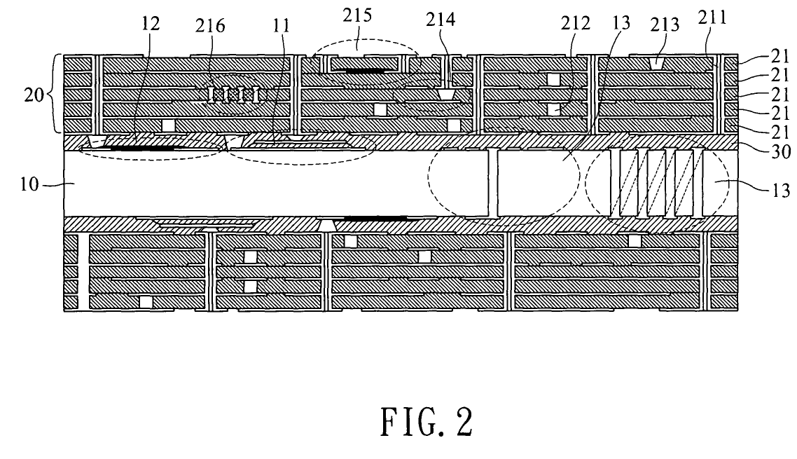

FIG. 2 shows a sectional view of a second embodiment of the invention. The construction different from that of the first embodiment is that each organic substrate 20 is also embedded with passive components, such as capacitors 214, resistors 215 and inductors 216, according to the circuit design for meeting the requirements of complicated multi-functional systems.

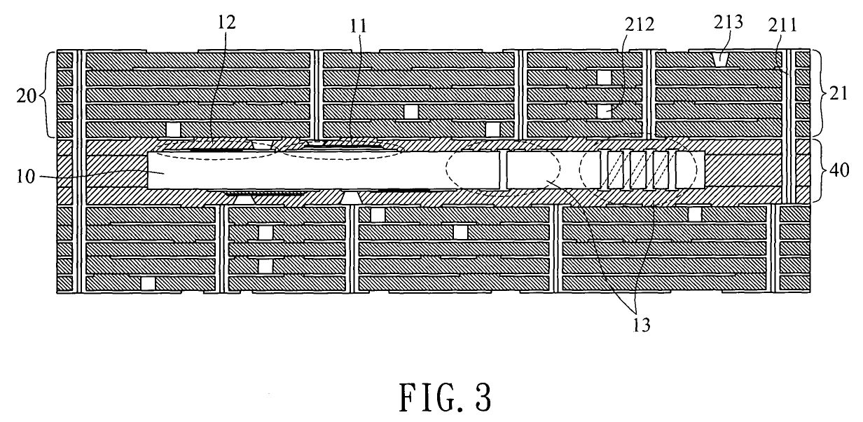

FIG. 3 shows a sectional view of a third embodiment of the invention. The construction different from that of the first embodiment is that the inorganic substrate 10 is made of a ceramic substrate. The passive components are all embedded in the ceramic substrate.

The inorganic substrate 10 is covered by a covering layer 40 and bonded with two organic substrate 20 fixed outside, so that the inorganic substrate 10 is fully covered the organic substrate 20. The covering layer 40 also includes circuit for providing electrical connections between the passive components and the organic substrate 20. Several inorganic substrates 10 with different passive components can be designed and embedded according to circuit requirements. Each organic substrate 20 is also embedded with unshown passive components, such as capacitors, resistors and inductors, according to the circuit design and improvement of its functions.

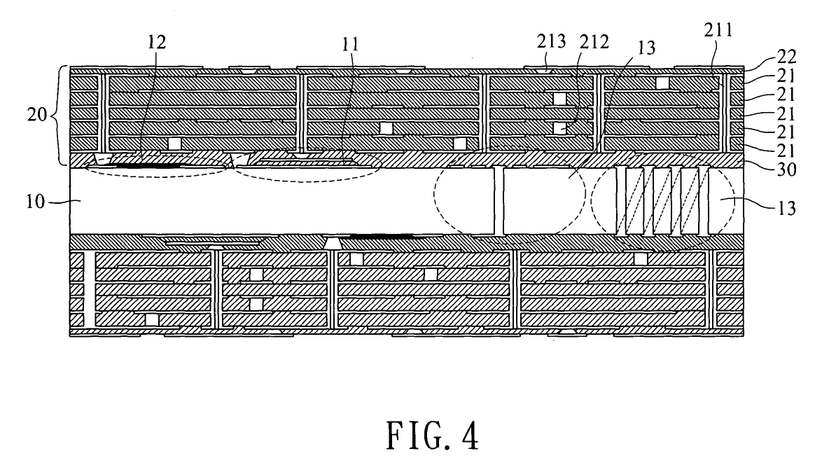

FIG. 4 shows a sectional view of a fourth embodiment of the invention. The construction different from that of the first embodiment is that the outer printed circuit board 21 is formed with a build-up substrate 22 through build-up process. The build-up process provides delicate circuits with thinner leads and holes than that of conventional printed circuit board so as to attain a high-density package. Also, each organic substrate 20 can be embedded with unshown passive component, such as capacitors, resistors and inductors, according to the circuit design for meeting the requirements of complicated multi-functional systems.

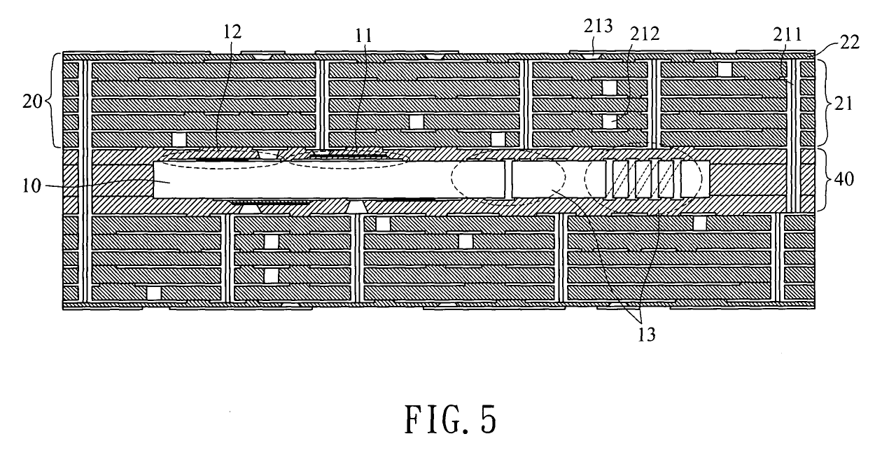

FIG. 5 shows a sectional view of a fifth embodiment of the invention. The construction different from that of the fourth embodiment is that the inorganic substrate 10 is covered by a covering layer 40 and bonded with two organic substrates 20 fixed outside, so that the inorganic substrate 10 is fully covered the organic substrates 20. The covering layer 40 also includes circuit for providing electrical connections between the passive components and the organic substrates 20. Several inorganic substrates 10 with different passive components can be designed and embedded according to circuit requirements.

After each printed circuit board 21 is formed, a build-up substrate 22 is formed through build-up process on the outer printed circuit board 21. The build-up process provides delicate circuits with thinner leads and holes to attain a higher-density layout. Also, each organic substrate 20 can be embedded with unshown passive components, such as capacitors, resistors and inductors, according to the circuit design and improvement of its functions.

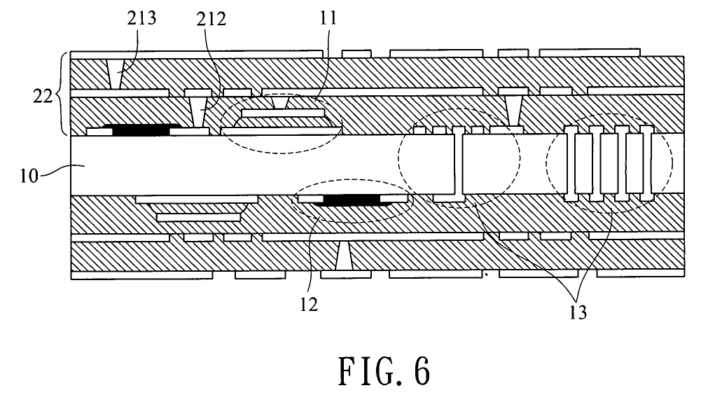

FIG. 6 shows a sectional view of a sixth embodiment of the invention. The organic substrate 20 is directly formed with a build-up substrate 22 through build-up process. The build-up process provides delicate circuits with thinner leads and holes than that of conventional printed circuit board so as to attain a high-density package. Also, each organic substrate 20 can be embedded with unshown passive component, such as capacitors, resistors and inductors, according to the circuit design for meeting the requirements of complicated multi-functional systems.

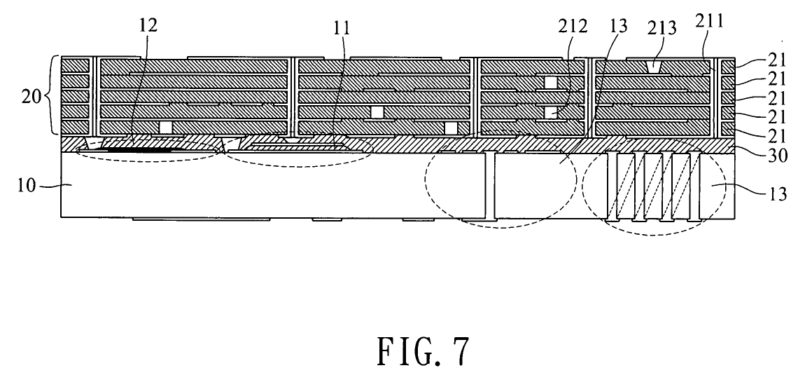

FIG. 7 shows a sectional view of a seventh embodiment of the invention. The construction different from that of the first embodiment is that each printed circuit board 21 of the organic substrate 20 is formed by overlapping, plating, drilling, etching and other processes and made one after one aside the inorganic substrate 10. The overlapping includes pressing or bonding. The electrical connections between the passive components and the chip carrier or I/O pads is made by via holes 211, buried holes 212 and blind holes 213 formed on the circuit layers 21.

The second embodiment, fourth embodiment and sixth embodiment can also be made, like the seventh embodiment, with only one side of the inorganic substrate 10 being formed with an organic substrate 20. Therefore, the invention can be practiced in different ways according to different requirements to the inorganic substrate and the organic substrate.

The invention being thus described, it will be obvious that the same may be varied in many ways. Such variations are not to be regarded as a departure from the spirit and scope of the invention, and all such modifications as would be obvious to one skilled in the art are intended to be included within the scope of the following claims.

What is claimed is:

1. A compositive laminate substrate, comprising:
at least an inorganic substrate having at least a passive component formed thereon; and
two organic substrates, located on two sides of said inorganic substrate, having circuits for electrical connections between outer input/output ports and said passive component of said inorganic substrate through said organic substrates.

2. The compositive laminate substrate according to claim 1 wherein the material of said inorganic substrate is selected from the group consisting of ceramic, silicon and glass.

3. The compositive laminate substrate according to claim 2 wherein, with ceramic material, said passive component is made from the process selected from the group consisting of thick film process and thin film process.

4. The compositive laminate substrate according to claim 2 wherein, with silicon material, said passive component is made from a semiconductor fabrication process.

5. The compositive laminate substrate according to claim 1 wherein said passive component is selected from the group consisting of capacitor, inductor and resistor.

6. The compositive laminate substrate according to claim 1 wherein each of said organic substrate is composed of a plurality of print circuit boards.

7. The compositive laminate substrate according to claim 6 wherein the circuit of the print circuit boards are made separately, and then stacked together to form said organic substrates.

8. The compositive laminate substrate according to claim 6 wherein the circuit of the print circuit boards are made separately, then stack the print circuit boards together, and finally form the circuit of a surface layer with build-up process to form said organic substrates.

9. The compositive laminate substrate according to claim 1 wherein at least one of said organic substrate further comprises at least a passive component.

10. The compositive laminate substrate according to claim 9 wherein said passive component on said organic substrate is selected from the group consisting of capacitor, inductor and resistor.

11. The compositive laminate substrate according to claim 1 wherein said organic substrate is made on said inorganic substrate with build-up process.

12. The compositive laminate substrate according to claim 1 further comprises a covering layer, for covering said inorganic substrate, integrating with said organic substrate, and fully embedding said inorganic substrate in said the organic substrate, said covering layer further comprises circuits for providing electrical connections between said passive component and said organic substrate.

13. The compositive laminate substrate according to claim 1 further comprises a bonding layer formed between said inorganic substrate and at least one of said organic substrate for bonding the two.

14. A compositive laminate substrate, comprising:
an inorganic substrate having at least a passive component formed thereon; and
an organic substrate, located on one side of said inorganic substrate, having circuits for electrical connections between outer input/output ports and said passive component on said inorganic substrate.

15. The compositive laminate substrate according to claim 14 wherein material of said inorganic substrate is selected from the group consisting of ceramic, silicon and glass.

16. The compositive laminate substrate according to claim 15 wherein, with ceramic material, said passive component is made from a process selected from the group consisting of thick film process and thin film process.

17. The compositive laminate substrate according to claim 15 wherein, with silicon material, said passive component is made from a semiconductor fabrication process.

18. The compositive laminate substrate according to claim 14 wherein said passive component is selected from the group consisting of capacitor, inductor and resistor.

19. The compositive laminate substrate according to claim 14 wherein said organic substrate is composed of a plurality of print circuit boards.

20. The compositive laminate substrate according to claim 19 wherein the circuit of said print circuit boards of said organic substrate are made separately, and then stacked together to form said organic substrate.

21. The compositive laminate substrate according to claim 19 wherein the circuit of said print circuit boards of said organic substrate are made separately, then stack the print circuit boards together, and finally form the circuit of a surface layer with build-up process to form said organic substrate.

22. The compositive laminate substrate according to claim 14 wherein said organic substrate further comprises at least a passive component.

23. The compositive laminate substrate according to claim 22 wherein said passive component on said organic substrate is selected from the group consisting of capacitor, inductor and resistor.

24. The compositive laminate substrate according to claim 14 wherein said organic substrate is made on said inorganic substrate with build-up process.

25. The compositive laminate substrate according to claim 14 further comprises a bonding layer formed between said inorganic substrate and said organic substrate for bonding the two.
